(19) United States
(12) Patent Application Publication
(10) Pub. No.: US 2020/0066647 A1
(43) Pub. Date: Feb. 27, 2020

(54) SEMICONDUCTOR DEVICE

(71) Applicant: TOYOTA JIDOSHA KABUSHIKI KAISHA, Toyota-shi (JP)

(72) Inventors: Ryosuke SHIIZAKI, Seto-shi (JP); Akinori SAKAKIBARA, Toyota-shi (JP); Shingo TSUCHIMOCHI, Nagakute-shi (JP)

(73) Assignee: TOYOTA JIDOSHA KABUSHIKI KAISHA, Toyota-shi (JP)

(21) Appl. No.: 16/520,428

(22) Filed: Jul. 24, 2019

(30) Foreign Application Priority Data
Aug. 22, 2018 (JP) 2018-155594

(51) Int. Cl. H01L 23/532; H01L 23/15; H01L 23/373

(52) U.S. Cl. CPC H01L 23/53295; H01L 23/3735; H01L 23/3731; H01L 23/15

(57) ABSTRACT

A semiconductor device disclosed herein may include: a semiconductor element; and a stacked substrate on which the semiconductor element is disposed, wherein the stacked substrate includes an insulator substrate, a first conductive layer and a second conductive layer, the first conductive layer being disposed on one side of the insulator substrate, and the second conductive layer being disposed on another side of the insulator substrate, a volume of the second conductive layer is smaller than a volume of the first conductive layer, a material of the insulator substrate has a smaller coefficient of linear thermal expansion and a higher rigidity than a material of the first conductive layer and a material of the second conductive layer, and a protrusion is provided on the one side of the insulator substrate, and the protrusion protrudes along a side surface of the first conductive layer.

### CROSS-REFERENCE TO RELATED APPLICATION

This application claims priority to Japanese Patent Application No. 2018-155594, filed on Aug. 22, 2018, contents of which are incorporated herein by reference.

### TECHNICAL FIELD

The technology disclosed herein relates to a semiconductor device.

### BACKGROUND

Japanese Patent Application Publication No. 2013-074254 discloses a semiconductor device. This semiconductor device includes a semiconductor element, and a stacked substrate on which the semiconductor element is disposed. The stacked substrate includes an insulator substrate, and conductive layers provided on opposite surfaces of the insulator substrate.

### SUMMARY

Generally, a semiconductor device experiences a temperature rise as it is energized, and each of its constituent members thermally expands in accordance with the temperature rise. At this occasion, its stacked substrate, which includes an insulator substrate and two opposite conductive layers with the insulator substrate interposed therebetween, may warp due to thermal expansion of each of the conductive layers. If the two conductive layers have different volumes from each other, in particular, forces of different magnitudes respectively from the conductive layers act upon the insulator substrate sandwiched by these conductive layers. In this case, relatively large warpage may occur in the insulator substrate (i.e., the stacked substrate). The insulator substrate, in particular, has a smaller coefficient of linear thermal expansion and a higher rigidity than each of the conductive layers. If large warpage of the insulator substrate occurs, excessively large stress may be therefore generated inside the insulator substrate undesirably. The present specification thus provides a technology capable of reducing warpage that occurs in an insulator substrate (i.e., a stacked substrate).

A semiconductor device disclosed herein may comprise: a semiconductor element; and a stacked substrate on which the semiconductor element is disposed, wherein the stacked substrate comprises an insulator substrate, a first conductive layer and a second conductive layer, the first conductive layer being disposed on one side of the insulator substrate, and the second conductive layer being disposed on another side of the insulator substrate, a volume of the second conductive layer is smaller than a volume of the first conductive layer, a material of the insulator substrate has a smaller coefficient of linear thermal expansion and a higher rigidity than a material of the first conductive layer and a material of the second conductive layer, and a protrusion is provided on the one side of the insulator substrate, and the protrusion protrudes along a side surface of the first conductive layer.

### BRIEF DESCRIPTION OF DRAWINGS

FIG. 1 is a top view showing an external appearance of a semiconductor device 10 in the present embodiment;

FIG. 2 shows a cross-sectional view along a line II-II in FIG. 1;

FIG. 3 is an exploded view showing an internal structure of the semiconductor device 10 with an encapsulant 16 omitted;

FIG, 4 is a circuit diagram showing a circuit structure of the semiconductor device 10;

FIG. 5 is a top perspective view showing a first inner conductive layer 26 of a first stacked substrate 20:

FIG. 6 is a bottom perspective view showing a first outer conductive layer 24 of the first stacked substrate 20;

FIG. 7 is a top perspective view showing a second inner conductive layer 36 of a second stacked substrate 30;

FIG. 8 is a top perspective view showing a third inner conductive layer 46 of a third stacked substrate 40;

FIG. 9 is an enlarged view of a portion IX in FIG. 2 with the encapsulant 16 omitted;

FIGS. 10A-D are a cross-sectional view showing a variation of a protrusion 22a;

FIGS. 11A-C are a bottom view showing a variation of the protrusion 22a; and

FIGS. 12A-B are a bottom view showing a variation of the protrusion 22a.

### DETAILED DESCRIPTION

In an embodiment of the present technology, a semiconductor device may comprise: a semiconductor element; and a stacked substrate on which the semiconductor element is disposed, wherein the stacked substrate comprises an insulator substrate, a first conductive layer and a second conductive layer, the first conductive layer being disposed on one side of the insulator substrate, and the second conductive layer being disposed on another side of the insulator substrate, a volume of the second conductive layer is smaller than a volume of the first conductive layer, a material of the insulator substrate has a smaller coefficient of linear thermal expansion and a higher rigidity than a material of the first conductive layer and a material of the second conductive layer, and a protrusion is provided on the one side of the insulator substrate, and the protrusion protrudes along a side surface of the first conductive layer.

In the semiconductor device described above, the protrusion is provided on the one side of the insulator substrate, and the protrusion protrudes along the side surface of the first conductive layer. The insulator substrate has a smaller coefficient of linear thermal expansion and a higher rigidity than the first conductive layer, and therefore the protrusion of the insulator substrate can suppress thermal expansion of the first conductive layer. Since the volume of the first conductive layer in particular is larger than the volume of the second conductive layer, larger thermal expansion could occur in the first conductive layer than in the second conductive layer. Accordingly, the suppression of thermal expansion of the first conductive layer where relatively large thermal expansion occurs reduces warpage of the insulator substrate caused by a difference in thermal expansion between the two conductive layers.

In an embodiment of the present technology, in a planar view of the stacked substrate, the first conductive layer may have a polygonal shape including a plurality of corners and each of the corners may be in contact with the protrusion. Stress concentration tends to occur particularly at the corners of the first conductive layer. Provision of the protrusion for such.

corners of the first conductive layer can effectively reduce warpage that occurs in the insulator substrate.

In the embodiment described above, in the planar view of the stacked substrate, the protrusion may include a first portion in contact with at least one of the corners and a second portion extending from the first portion along an outer edge of the first conductive layer. In this case, in a cross section perpendicular to a direction along the outer edge of the first conductive layer, a cross-sectional area of the first portion may be larger than a cross-sectional area of the second portion. According to such a configuration, strength (rigidity) of the protrusion can be enhanced in the first portion in contact with the comer(s) of the first conductive layer.

In an embodiment of the present technology, in a planar view of the stacked substrate, the protrusion may continuously extend along an entirety of the outer edge of the first conductive layer so as to surround the first conductive layer. According to such a configuration, rigidity of the protrusion as a whole is increased, and the effect by the protrusion of suppressing thermal expansion of the first conductive layer is enhanced.

In an embodiment of the present technology, in a planar view of the stacked substrate, at least a part of the protrusion may be located outside relative to an outer edge of the second conductive layer. In this case, the protrusion enhances rigidity of the insulator substrate close to an end of the second conductive layer. Thermal expansion of the second conductive layer is thereby suppressed.

In an embodiment of the present technology, a height of the protrusion may be substantially equal to a height of the first conductive layer. In this case, the protrusion achieves a large volume and a relatively high rigidity. The effect of suppressing thermal expansion of the first conductive layer by the protrusion is thereby enhanced.

In an embodiment of the present technology, the insulator substrate may be constituted of a ceramic material.

Representative, non-limiting examples of the present disclosure will now be described in further detail with reference to the attached drawings. This detailed description is merely intended to teach a person of skill in the art further details for practicing aspects of the present teachings and is not intended to limit the scope of the present disclosure. Furthermore, each of the additional features and teachings disclosed below may be utilized separately or in conjunction with other features and teachings to provide improved semiconductor devices, as well as methods for using and manufacturing the same.

Moreover, combinations of features and steps disclosed in the following detailed description may not be necessary to practice the present disclosure in the broadest sense, and are instead taught merely to particularly describe representative examples of the present disclosure.

Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### Embodiments

With reference to drawings, a semiconductor device 10 in an embodiment will be described. The semiconductor device 10 is adopted for a power control device of an electric vehicle for example, and can configure at least a part of a power conversion circuit such as a converter or an inverter. The electric vehicle herein mentioned widely refers to automobiles each having a motor that drives wheels, and examples of the electric vehicle include an electric vehicle charged with external power, a hybrid vehicle having an engine in addition to a motor, a fuel-cell vehicle powered by a fuel cell, and the like.

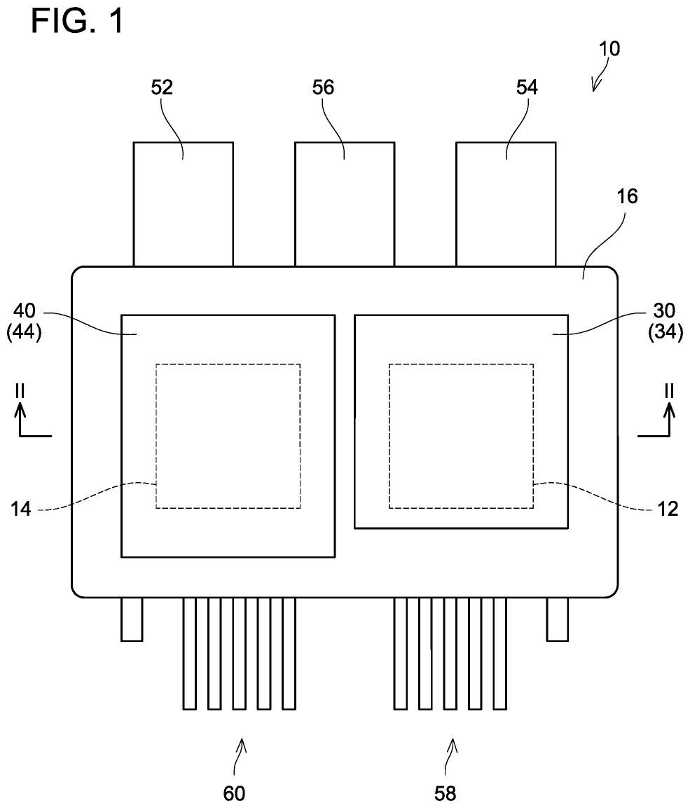

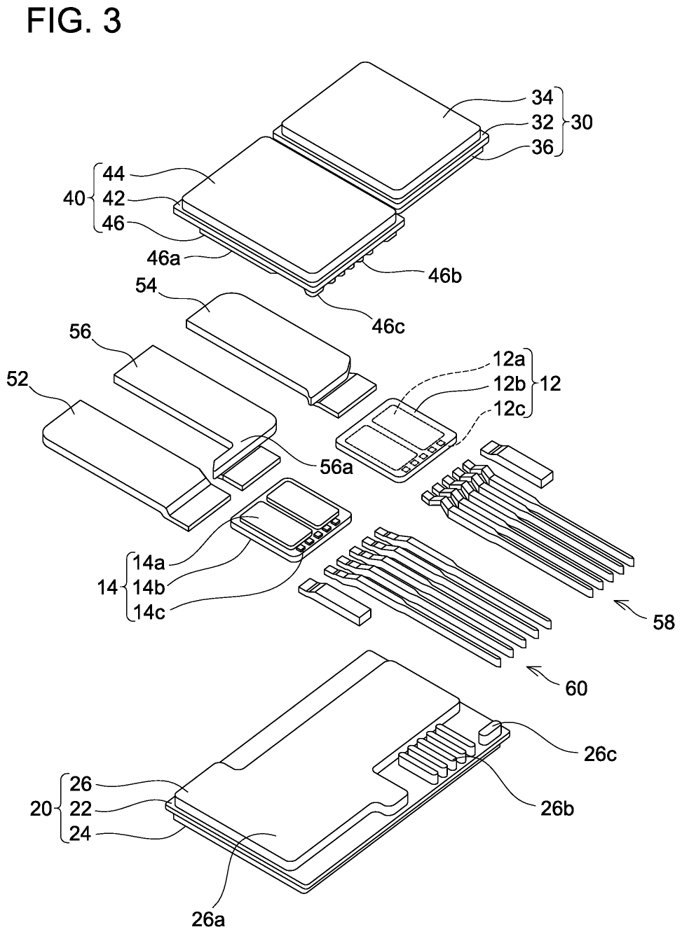

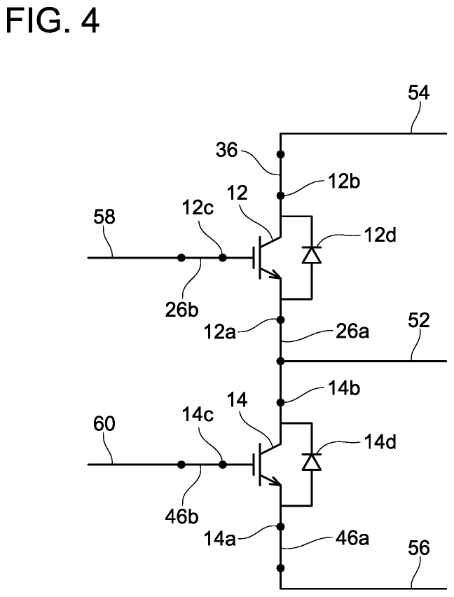

As shown in FIGS. 1 to 4, the semiconductor device 10 includes a first semiconductor element 12, a second semiconductor element 14, and an encapsulant 16. The first semiconductor element 12 and the second semiconductor element 14 are encapsulated within the encapsulant 16. The encapsulant 16 is constituted of an insulating material. The encapsulant 16 in the present embodiment is constituted of a thermosetting resin such as, for example, an epoxy resin, but is not particularly limited thereto. The encapsulant 16 has approximately a plate shape, and comprises a front surface 16a and a back surface 16b located opposite to the front surface 16a.

The first semiconductor element 12 includes a front electrode 12a, a back electrode 12b, and a plurality of signal electrodes 12c. The front electrode 12a and the signal electrodes 12c are located on a front surface of the first semiconductor element 12, and the back electrode 12b is located on a back surface of the first semiconductor element 12. The first semiconductor element 12 is a switching element that electrically connects and disconnects the front electrode 12a and the back electrode 12b. The first semiconductor element 12 in the present embodiment is an Insulated Gate Bipolar Transistor (IGBT), but is not particularly limited thereto, and the front electrode 12a is an emitter electrode and the back electrode 12b is a collector electrode. Moreover, the first semiconductor element 12 contains a freewheeling diode 12d in addition to the IGBT. Notably, as another embodiment, the first semiconductor element 12 may also be a Metal-Oxide-Semiconductor Field-Effect Transistor (MOSFET). In this case, the front electrode 12a may be a source electrode and the back electrode 12b may be a drain electrode.

Similarly, the second semiconductor element 14 includes a front electrode 14a, a back electrode 14b, and a plurality of signal electrodes 14c. The front electrode 14a and the signal electrodes 14c are located on a front surface of the second semiconductor element 14, and the back electrode 14b is located on a back surface of the second semiconductor element 14. The second semiconductor element 14 is a switching element that electrically connects and disconnects the front electrode 14a and the back electrode 14b. The second semiconductor element 14 in the present embodiment is an IGBT, but is not particularly limited thereto, and the front electrode 14a is an emitter electrode and the back electrode 14b is a collector electrode. Moreover, the second semiconductor element 14 also contains a freewheeling diode 14d in addition to the IGBT. Notably, the second semiconductor element 14 may also be a MOSFET, and the front electrode 14a may be a source electrode and the back electrode 14b may be a drain electrode.

The first semiconductor element 12 and the second semiconductor element 14 in the present embodiment have same structures, and are disposed in orientations inverted to each other, but are not particularly limited thereto. It should be noted that, as another embodiment, the first semiconductor element 12 and the second semiconductor element 14 may have different structures. For example, the first semiconductor element 12 and the second semiconductor element 14 may he switching elements structures of which are different from each other. Alternatively, the first semiconductor element 12 may be a switching element and the second semiconductor element 14 may be a diode element. Various types of power semiconductor elements may be adopted for the first semiconductor element 12 and the second semiconductor element 14.

The semiconductor device 10 further includes a first stacked substrate 20, a second stacked substrate 30, and a third stacked substrate 40. The first stacked substrate 20 is larger than the second stacked substrate 30 and the third stacked substrate 40, and has both of the first semiconductor element 12 and the second semiconductor element 14 disposed thereon. The first stacked substrate 20 is opposed to the second stacked substrate 30 with the first semiconductor element 12 interposed between the first stacked substrate 20 and the second stacked substrate 30. In other words, the first semiconductor element 12 is disposed between the first stacked substrate 20 and the second stacked substrate 30. The first stacked substrate 20 is opposed to the third stacked substrate 40 with the second semiconductor element 14 interposed between the first stacked substrate 20 and the third stacked substrate 40. In other words, the second semiconductor element 14 is disposed between the first stacked substrate 20 and the third stacked substrate 40.

The first stacked substrate 20 comprises a first insulator substrate 22, a first outer conductive layer 24 provided on one side of the first insulator substrate 22, and a first inner conductive layer 26 provided on another side of the first insulator substrate 22. The first inner conductive layer 26 is electrically connected to the first semiconductor element 12 and the second semiconductor element 14 within the encapsulant 16. On the other hand, the first outer conductive layer 24 is exposed to an outside at the back surface 16b of the encapsulant 16. The first stacked substrate 20 thereby configures a part of an electric circuit, and additionally functions as a heat-radiating plate that rejects heat of the first semiconductor element 12 and the second semiconductor element 14 to an outside. Moreover, a volume of the first inner conductive layer 26 is smaller than a volume of the first outer conductive layer 24. In other words, the volume of the first outer conductive layer 24 is larger than the volume of the first inner conductive layer 26. Accordingly, the heat-radiating effect of the first stacked substrate 20 can be improved. Here, the first outer conductive layer 24 is an example of “a first conductive layer” in the technology disclosed herein, and the first inner conductive layer 26 is an example of “a second conductive layer” in the technology disclosed herein.

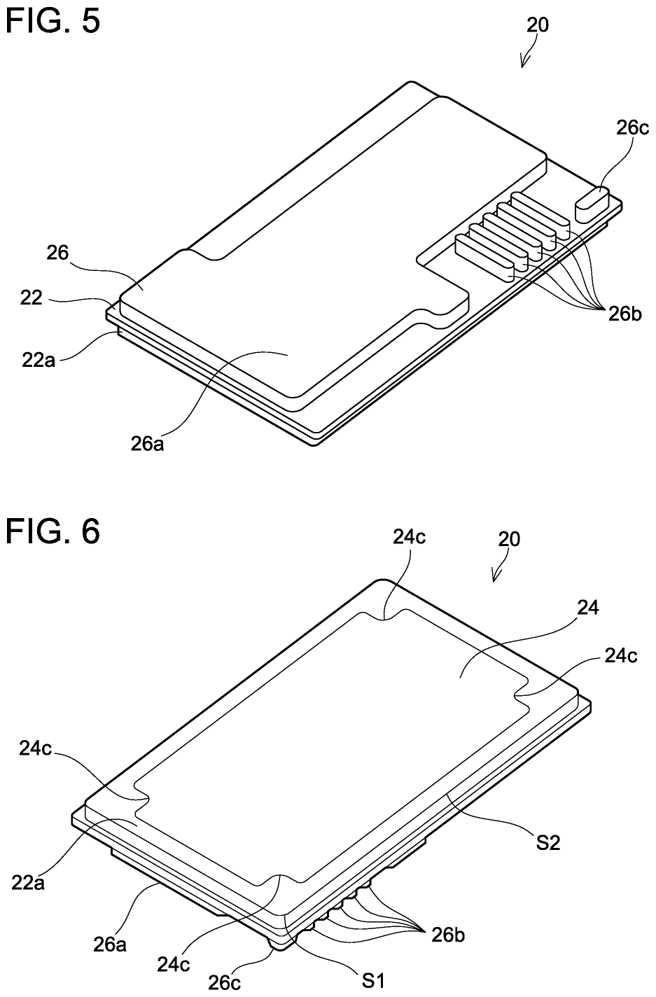

As shown in FIG. 5, the first inner conductive layer 26 of the first stacked substrate 20 comprises a plurality of regions 26a, 26b, and 26c separated from one another on the first insulator substrate 22. The regions 26a, 26b, and 26c include a main region 26a, a plurality of signal regions 26b, and a floating region 26c. The main region 26a is electrically connected to the front electrode 12a of the first semiconductor element 12 and the back electrode 14b of the second semiconductor element 14. Due to this, the first semiconductor element 12 and the second semiconductor element 14 are connected to each other via the main region 26a of the first inner conductive layer 26. Each of the signal regions 26b is electrically connected to a corresponding one of the signal electrodes 12c of the first semiconductor element 12. As an example, in the present embodiment, the first semiconductor element 12 and the second semiconductor element 14 are directly soldered to the first inner conductive layer 26 of the first stacked substrate 20. It should be noted that, as another embodiment, at least one of the first semiconductor element 12 and the second semiconductor element 14 may also be connected to the first inner conductive layer 26 of the first stacked substrate 20 via another member such as a conductor spacer or a bonding wire.

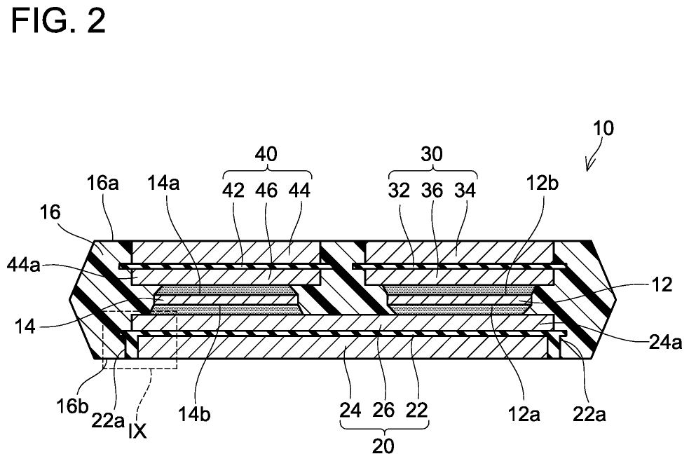

As shown in FIGS. 2 and 6, the first insulator substrate 22 of the first stacked substrate 20 further includes a protrusion 22a provided on the one side of the first insulator substrate 22. The protrusion 22a protrudes from the first insulator substrate 22 along a side surface of the first outer conductive layer 24 (see FIG. 2). As an example, the protrusion 22a has substantially a frame shape. The protrusion 22a can be configured as a member integrated with the first insulator substrate 22.

The second stacked substrate 30 comprises a second insulator substrate 32, a second outer conductive layer 34 provided on one side of the second insulator substrate 32, and a second inner conductive layer 36 provided on another side of the second insulator substrate 32. The second inner conductive layer 36 is electrically connected to the first semiconductor element 12 within the encapsulant 16. On the other hand, the second outer conductive layer 34 is exposed to an outside at the front surface 16a of the encapsulant 16. Due to this, the second stacked substrate 30 configures a part of an electric circuit, and additionally functions as a heat-radiating plate that rejects heat of the first semiconductor element 12 to an outside.

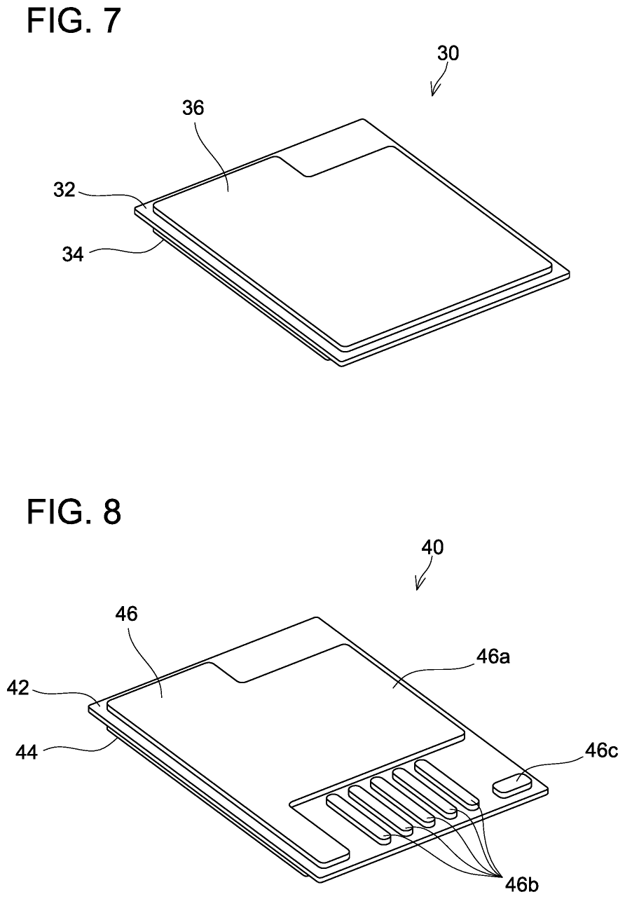

As shown in FIG. 7, the second inner conductive layer 36 of the second stacked substrate 30 only comprises a single region. The second inner conductive layer 36, which has a single region, is electrically connected to the back electrode 12b of the first semiconductor element 12. Due to this, the second inner conductive layer 36 of the second stacked substrate 30 is electrically connected to the main region 26a of the first inner conductive layer 26 of the first stacked substrate 20 via the first semiconductor element 12. As an example, in the present embodiment, the first semiconductor element 12 is directly soldered to the second inner conductive layer 36 of the second stacked substrate 30. It should be noted that, as another embodiment, the first semiconductor element 12 may also be connected to the second inner conductive layer 36 of the second stacked substrate 30 via another member such as a conductor spacer or a bonding wire. Moreover, the second inner conductive layer 36 of the second stacked substrate 30 may include a plurality of regions separated from one another on the second insulator substrate 32, as in the first inner conductive layer 26 of the first stacked substrate 20.

The third stacked substrate 40 includes a third insulator substrate 42, a third outer conductive layer 44 provided on one side of the third insulator substrate 42, and a third inner conductive layer 46 provided on another side of the third insulator substrate 42. The third inner conductive layer 46 is electrically connected to the second semiconductor element 14 within the encapsulant 16. On the other hand, the third outer conductive layer 44 is exposed to an outside at the front surface 16a of the encapsulant 16. Due to this, the third stacked substrate 40 configures a part of an electric circuit, and additionally functions as a heat-radiating plate that rejects heat of the second semiconductor element 14 to an outside. In the present embodiment, a size of the third stacked substrate 40 is larger than a size of the second stacked substrate 30, but these sizes are not particularly limited thereto. It should be noted that the size of the third stacked substrate 40 may be the same as, or smaller than the size of the second stacked substrate 30.

As shown in FIG. 8, the third inner conductive layer 46 of the third stacked substrate 40 comprises a plurality of regions 46a, 46b and 46c separated from one another on the third insulator substrate 42. The regions 46a, 46b, and 46c include a main region 46a, a plurality of signal regions 46b, and a floating region 46c. The main region 46a is connected to the front electrode 14a of the second semiconductor element 14. Due to this, the third inner conductive layer 46 of the third stacked substrate 40 is electrically connected to the main region 26a of the first inner conductive layer 26 of the first stacked substrate 20 via the second semiconductor element 14. Each of the signal regions 46b is electrically connected to a corresponding one of the signal electrodes 14c of the second semiconductor element 14. As an example, in the present embodiment, the second semiconductor element 14 is directly soldered to the third inner conductive layer 46 of the third stacked substrate 40. It should be noted that, as another embodiment, the second semiconductor element 14 may also be connected to the third inner conductive layer 46 of the third stacked substrate 40 via another member such as a conductor spacer or a bonding wire.

As an example, each of the three stacked substrates 20, 30, and 40 in the present embodiment is a Direct Bonded Copper (DBC) substrate. The insulator substrates 22, 32, and 42 are constituted of ceramic such as, for example, aluminum oxide, silicon nitride, aluminum nitride, and the like. Moreover, the outer conductive layers 24, 34, and 44 and the inner conductive layers 26, 36, and 46 are constituted of copper. The insulator substrates 22, 32, and 42 are constituted of a material that has a smaller coefficient of linear thermal expansion and a higher rigidity than the outer conductive layers 24, 34, and 44 and the inner conductive layers 26, 36, and 46. It should be noted that each of the three stacked substrates 20, 30, and 40 is not limited to a DBC substrate, and may also be, for example, a Direct Bonded Aluminum (DBA) substrate. Alternatively, the insulator substrates 22, 32, and 42 may each have a structure different from that of a DBC substrate or a DBA substrate. Each configuration of the stacked substrates 20, 30, and 40 is not limited to a particular one. The three stacked substrates 20, 30, and 40 may only need to respectively comprise the insulator substrates 22, 32, and 42 that are constituted of an insulating material, and the outer conductive layers 24, 34, and 44 and the inner conductive layers 26, 36, and 46 constituted of a conductor such as metal. What connection methods are used for: the first insulator substrate 22 and each of the conductive layers 24 and 26 in the first stacked substrate 20; the insulator substrate 32 and each of the conductive layers 34 and 36 in the second stacked substrate 30 and the insulator substrate 42 and each of the conductive layers 44 and 46 in the third stacked substrate 40 are not limited to particular ones, either.

As shown in FIGS. 1, 3 and 4, the semiconductor device 10 further comprises a first power terminal 52, a second power terminal 54, and a third power terminal 56. These three power terminals 52, 54 and. 56 protrude from the encapsulant 16 in a same direction, and extend parallel to each another. The three power terminals 52, 54 and 56 are constituted of a conductor such as copper or another metal. The three power terminals 52, 54 and 56 may be prepared altogether as a single lead frame in course of manufacturing the semiconductor device 10, but are not particularly limited thereto.

The first power terminal 52 is electrically connected to the first stacked substrate 20 within the encapsulant 16. Specifically, the first power terminal 52 is joined, between the first stacked substrate 20 and the third stacked substrate 40, to the main region 26a of the first inner conductive layer 26 of the first stacked substrate 20. Due to this, the first power terminal 52 is electrically connected to the front electrode 12a of the first semiconductor element 12 and the back electrode 14b of the second semiconductor element 14 via the main region 26a of the first inner conductive layer 26.

The second power terminal 54 is electrically connected to the second stacked substrate 30 within the encapsulant 16. Specifically, the second power terminal 54 is joined to the second inner conductive layer 36 of the second stacked substrate 30 between the first stacked substrate 20 and the second stacked substrate 30. Due to this, the second power terminal 54 is electrically connected to the back electrode 12b of the first semiconductor element 12 via the second inner conductive layer 36.

The third power terminal 56 is electrically connected to the third stacked substrate 40 within the encapsulant 16. Specifically, the third power terminal 56 is joined to the third inner conductive layer 46 of the third stacked substrate 40 between the first stacked substrate 20 and the third stacked substrate 40. Due to this, the third power terminal 56 is electrically connected to the front electrode 14a of the second semiconductor element 14 via the third inner conductive layer 46.

As shown in FIGS. 1, 3, and 4, the semiconductor device 10 further comprises a plurality of first signal terminals 58 and a plurality of second signal terminals 60. These signal terminals 58 and 60 protrude from the encapsulant 16 in a same direction, and extend parallel to each another. The signal terminals 58 and 60 are constituted of a conductor such as copper or another metal.

The first signal terminals 58 are electrically connected to the first stacked substrate 20 within the encapsulant 16. Specifically, each of the first signal terminals 58 is joined to a corresponding one of the signal regions 26b of the first inner conductive layer 26 of the first stacked substrate 20 (see FIG. 5). Due to this, each of the first signal terminals 58 is electrically connected to the corresponding one of the signal electrodes 12c of the first semiconductor element 12 via the corresponding one of the signal regions 26b of the first inner conductive layer 26. As an example, in the present embodiment, the first signal terminals 58 are directly soldered to the signal regions 26b of the first inner conductive layer 26, respectively. It should be noted that, as another embodiment, the first signal terminals 58 may be connected to the signal regions 26b (or the signal electrodes 12c of the first semiconductor element 12) via other members such as conductor spacers or bonding wires, respectively.

The second signal terminals 60 are electrically connected to the third stacked substrate 40 within the encapsulant 16. Specifically, each of the second signal terminals 60 is joined to a corresponding one of the signal regions 46b of the third inner conductive layer 46 of the third stacked substrate 40 (see FIG. 8). Due to this, each of the second signal terminals 60 is electrically connected to the corresponding one of the signal electrodes 14c of the second semiconductor element 14 via the corresponding one of the signal regions 46b of the third inner conductive layer 46. An example, in the present embodiment, the second signal terminals 60 are directly soldered to the signal regions 46b of the third inner conductive layer 46, respectively. It should be noted that, as another embodiment, the second signal terminals 60 may be connected to the signal regions 46b (or the signal electrodes 14c of the second semiconductor element 14) via other members such as conductor spacers or bonding wires, respectively.

As shown in FIG. 6, in the semiconductor device 10 described above, the protrusion 22a is provided on the one side of the first insulator substrate 22, and the protrusion 22a protrudes along the side surface of the first outer conductive layer 24. As mentioned above, the first insulator substrate 22 has a smaller coefficient of linear thermal expansion and a higher rigidity than the first outer conductive layer 24. Therefore, the protrusion 22a, which is configured integrally with the first insulator substrate 22, can suppress thermal expansion of the first outer conductive layer 24. In the first stacked substrate 20 in the present embodiment, in particular, since the volume of the first outer conductive layer 24 is larger than the volume of the first inner conductive layer 26, larger thermal expansion could occur in the first outer conductive layer 24 than in the first inner conductive layer 26. Accordingly, the suppression of thermal expansion of the first outer conductive layer 24, where thermal expansion is relatively large, reduces warpage of the first insulator substrate 22 caused by a difference in thermal expansion between the two conductive layers 24 and 26.

Additionally, as mentioned above, in a planar view of the first stacked substrate 20, the protrusion 22a has a frame shape, and continuously extends along an entirety of an outer edge of the first outer conductive layer 24 so as to surround the first outer conductive layer 24. Such a configuration increases rigidity of the protrusion 22a as a whole, and enhances the effect brought forth by the protrusion 22a of suppressing thermal expansion of the first outer conductive layer 24. Moreover, since the first outer conductive layer 24 is surrounded by the protrusion 22a that is constituted of an insulating material, a creepage distance between the first outer conductive layer 24 and the first inner conductive layer 26 can be made long.

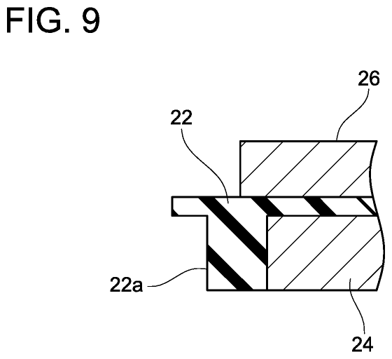

Additionally, as shown in FIG. 9, a height of the protrusion 22a is substantially equal to a height of the first outer conductive layer 24. The term “substantially equal” herein means that a difference between them is equal to or less than ±10 percent. The above-described configuration allows for a great volume of the protrusion 22a and also a relatively high rigidity thereof. Due to this, the effect brought forth by the protrusion 22a of suppressing thermal expansion of the first outer conductive layer 24 is further enhanced.

Additionally, in the planar view of the first stacked substrate 20, the protrusion 22a comprises first portions S1 respectively contacting corners 24c of the first outer conductive layer 24, and second portions 52. With regard to a cross section perpendicular to a direction along the outer edge of the first outer conductive layer 24, a cross-sectional area of each first portion S1 of the protrusion 22a is larger than a cross-sectional area of each second portion S2 of the protrusion 22a. In this case, the cross-sectional area of the protrusion 22a can be increased at the first portions S1 contacting the corners 24c of the first outer conductive layer 24 which are prone to concentrations of stress caused by thermal expansion of the first outer conductive layer 24. Due to this, stress per unit area that acts in a longitudinal direction of the protrusion 22a can be reduced. Accordingly, warpage of the first insulator substrate 22 is also reduced. Furthermore, as a size of the first portions S1 of the protrusion 22a is increased, the volume of the first outer conductive layer 24 is decreased. This mitigates imbalance in volume between the first outer conductive layer 24 and the first inner conductive layer 26, and warpage of the first insulator substrate 22 caused by a difference in thermal expansion between the two conductive layers 24 and 26 is further reduced.

Furthermore, at least a part of the protrusion 22a is located outside (at an outer side) relative to an outer edge of the first inner conductive layer 26 (see FIG. 9). In other words, provision of the protrusion 22a causes a part of the first insulator substrate 22 that is close to an end of the first inner conductive layer 26 to have a relatively large volume. In this case, rigidity of the part of the first insulator substrate 22 close to the end of the first inner conductive layer 26 is also partly enhanced by the protrusion 22a. Due to this, thermal expansion not only of the first outer conductive layer 24 but also of the first inner conductive layer 26 is suppressed.

The inventors have examined a value of stress that acts upon the first insulator substrate 22 (the first stacked substrate 20) in the semiconductor device 10 in the present embodiment. As mentioned before, the protrusion 22a in the present embodiment is provided along the entirety of the outer edge of the first outer conductive layer 24, and the height of the protrusion. 22a is substantially equal to the height of the first outer conductive layer 24. Additionally, the cross-sectional area of the protrusion 22a in its longitudinal direction is enlarged at the first portions S11 contacting the corners 24c of the first outer conductive layer 24. In such a manner, the stress that acts upon the first stacked substrate 20 had a maximum value of 692.2 MPa. In contrast to this, in a conventional structure in which the protrusion 22a is not provided in the first insulator substrate 22, the stress that acts upon the first stacked substrate 20 had a maximum value of 784.9 MPa. In other words, the stress that acts upon the first insulator substrate 22 is reduced by approximately 12% in comparison with the conventional structure. Notably, as another embodiment, even in a manner in which the cross-sectional area is not enlarged at the first portions S1, the stress that acts upon the first insulator substrate 22 had a maximum value of 731.3 MPa. In other words, even in the manner in which the cross-sectional area is not enlarged at the first portions S1, the stress that acts upon the first insulator substrate 22 is reduced by approximately 7% in comparison with the conventional structure.

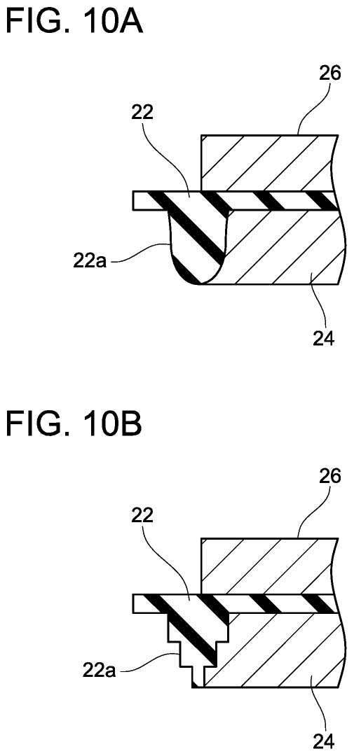

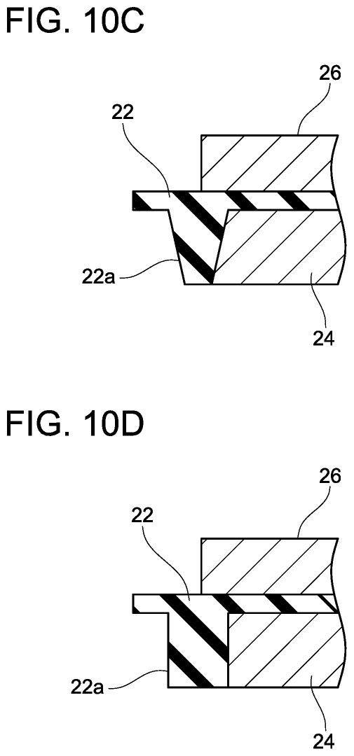

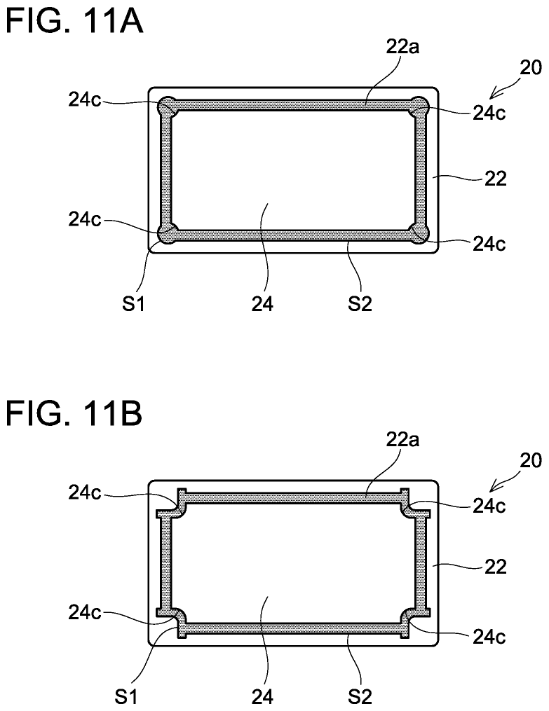

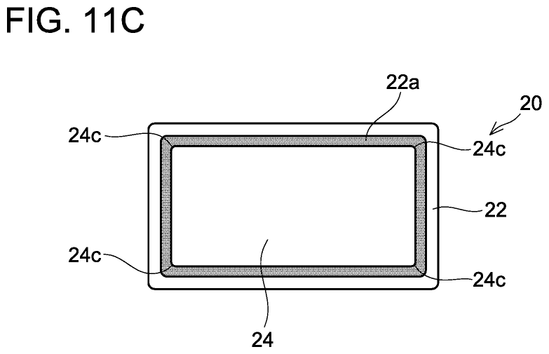

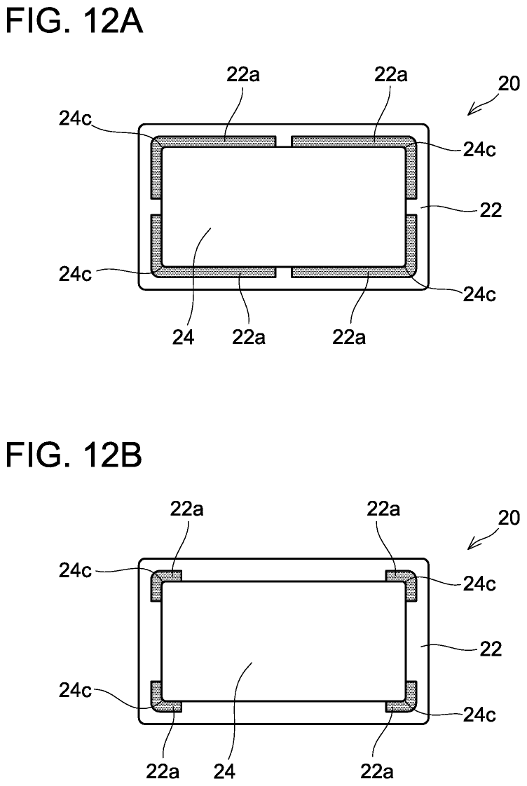

A form of the protrusion 22a is not limited to that in the present embodiment, and various embodiments can be implemented. With reference to FIGS. 10A-D, FIGS. 11A-C, and FIGS. 12A-B, variations of the protrusion 22a will be described. As shown in FIG. 10A, a shape of the cross section perpendicular to the longitudinal direction of the protrusion 22a may be approximately a semi-cylindrical shape. Alternatively, the shape of the cross section perpendicular to the longitudinal direction of the protrusion 22a may be approximately a triangular shape. Alternatively, as shown in FIG. 10B, the protrusion 22a may be provided such that its cross-sectional area sandwiched between its inner and outer edges increases in a stepwise manner. In case of such a configuration, the cross-sectional area of the protrusion 22a can be made larger than that of the triangular shape. Alternatively, as shown in FIG. 10C, the shape of the cross section perpendicular to the longitudinal direction of the protrusion 22a may be approximately a trapezoidal shape. Alternatively, as shown in FIG. 10(D), the shape of the cross section perpendicular to the longitudinal direction of the protrusion 22a may be approximately a rectangular shape as in the semiconductor device 10 in the embodiment.

FIGS. 11A-D and 12A-B show the first stacked substrate 20 in a bottom view seen from a first outer conductive layer 24 side. At this occasion, as shown in FIG. 11A, each of the first portions Si of the protrusion 22a contacting the corners 24c of the first outer conductive layer 24 may have substantially a circular shape. Moreover, as shown in FIG. 11B, each of the first portions S 1 of the protrusion 22a may have substantially an. L shape. With such configurations as well, the cross-sectional area of the protrusion 22a is increased at the first portions SI contacting the corners 24c of the first outer conductive layer 24. Accordingly, the stress per unit area that acts in the longitudinal direction of the protrusion 22a is reduced. However, the protrusion 22a may not necessarily need to have the first portions S1 that have a large cross-sectional area, and as shown in FIG. 11C, the cross-sectional area perpendicular to the longitudinal direction of the protrusion 22a may be uniform throughout its entirety.

Furthermore, the shape of the protrusion 22a is not limited to the frame shape that continuously surrounds the first outer conductive layer 24, and as shown in FIG. 12A, the protrusion 22a may surround the first outer conductive layer 24 discontinuously. Alternatively, as shown in FIG. 12B, a plurality of the protrusions 22a may be provided such that each of the corners 24c of the first outer conductive layer 24 contacts a corresponding one of protrusions 22a. According to such a configuration, provision of the protrusions 22a for the corners 24c that are prone to stress concentrations, in particular, can reduce warpage that occurs in the first insulator substrate 22.

As mentioned above, the protrusion 22a is configured as a member integral with the first insulator substrate 22. It should be noted that the protrusion 22a is not limited thereto, and may be constituted of a member separate from the first insulator substrate 22. In this case, a material that constitutes the protrusion 22a is not limited to ceramic, and may only need to have a relatively smaller coefficient of linear thermal expansion and a higher rigidity than the two conductive layers 24 and 26 that sandwich the first insulator substrate 22.

In manufacturing of the semiconductor device 10, the first stacked substrate 20 is assembled in form of a lead frame. Here, a method of fabricating the lead frame, especially the first outer conductive layer 24 and the first insulator substrate 22 of the first stacked substrate 20 Will be described. Other constituent members may be fabricated using conventional technologies.

As described above, the first outer conductive layer 24 of the first stacked substrate 20 is constituted of a conductor such as, for example, copper or another metal, and can be fabricated by a plurality of times of press work or the like, as an example. At first, in a first press work, a base material is processed to form a contour of a lead frame including the first outer conductive layer 24. At this occasion, a portion corresponding to the first outer conductive layer 24 is molded to conform to the protrusion 22a of the first stacked substrate 20. Next, in a second press work, the lead frame is processed to have an internal shape drilled or the like. In this second press work, each of the corners 24c of the first outer conductive layer 24 can also be processed to conform to the shape of the protrusion 22a. It should be noted that the method of fabricating the first outer conductive layer 24 is not limited to the press work described above, and can also be performed by etching or another processing method. Moreover, the corners 24c of the first outer conductive layer 24 may be processed in the first press work.

As described above, the first insulator substrate 22 of the first stacked substrate 20 is constituted of a material that has a smaller coefficient of linear thermal expansion and a higher rigidity (e.g. ceramic) than the material of the conductive layers 24 and 26. The first insulator substrate 22 of the first stacked substrate 20 can be fabricated by, for example, Cold Isostatic Pressing (CIP) molding or the like. As an example, in the CIP molding, granules of a raw material of the first insulator substrate 22 (ceramic or the like) are poured into a predetermined mold and pressed. A shape of the mold, at this occasion, may only need to be configured such that the protrusion 22a of the first insulator substrate 22 surrounds the outer edge of the first outer conductive layer 24. A molded body obtained through processing by the CIP molding is baked in a baking furnace such as, for example, a gas furnace or an electric furnace. The baking is followed by secondary processing such as grinding, machining, beveling, and the like, and the first insulator substrate 22 can thereby be fabricated. It should be noted that the method of fabricating the first insulator substrate 22 is not limited to the CIP molding, and may be implemented by press molding or another processing method.

What is claimed is:

1. A semiconductor device comprising:
a semiconductor element; and
a stacked substrate on which the semiconductor element is disposed,
wherein
the stacked substrate comprises an insulator substrate, a first conductive layer, and a second conductive layer, the first conductive layer being disposed on one side of the insulator substrate, and the second conductive layer being disposed on another side of the insulator substrate,
a volume of the second conductive layer is smaller than a volume of the first conductive layer,
a material of the insulator substrate has a smaller coefficient of linear thermal expansion and a higher rigidity than a material of the first conductive layer and a material of the second conductive layer, and
a protrusion is provided on the one side of the insulator substrate, and the protrusion protrudes along a side surface of the first conductive layer.

2. The semiconductor device according to claim 1, wherein in a planar view of the stacked substrate, the first conductive layer has a polygonal shape including a plurality of corners and each of the corners is in contact with the protrusion.

3. The semiconductor device according to claim 2, wherein
in the planar view of the stacked substrate, the protrusion comprises a first portion in contact with at least one of the corners and a second portion extending from the first portion along an outer edge of the first conductive layer, and
in a cross section perpendicular to a direction along the outer edge of the first conductive layer, a cross-sectional area of the first portion is larger than a cross-sectional area of the second portion.

4. The semiconductor device according to claim 1, wherein in a planar view of the stacked substrate, the protrusion continuously extends along an entirety of an outer edge of the first conductive layer so as to surround the first conductive layer.

5. The semiconductor device according to claim 1, wherein in a planar view of the stacked substrate, at least a part of the protrusion is located outside relative to an outer edge of the second conductive layer.

6. The semiconductor device according to claim 1, wherein a height of the protrusion is substantially equal to a height of the first conductive layer.

7. The semiconductor device according to claim 1, wherein the insulator substrate is constituted of a ceramic material.
